(19) United States
(12) Patent Application Publication
(10) Pub. No.: US 2009/0261376 A1
(43) Pub. Date: Oct. 22, 2009

(54) NITRIDE SEMICONDUCTOR LIGHT EMITTING DIODE AND METHOD OF FABRICATING THE SAME

(75) Inventor: Eu Jin Hwang, Jeonju-si (KR)

Correspondence Address: H.C. PARK & ASSOCIATES, PLC, 8500 LEESBURG PIKE, SUITE 7500, VIENNA, VA, 22182, US

(73) Assignee: SEOUL OPTO DEVICE CO., LTD., Ansan-si (KR)

(21) Appl. No.: 12/090,059

(22) PCT Filed: Jan. 29, 2007
(86) PCT No.: PCT/KR2007/000487

§ 371 Date: May 8, 2008

(30) Foreign Application Priority Data
Feb. 2, 2006 (KR) 10-2006-0010284

(51) Int. Cl. H01L 33/00

(52) U.S. Cl. 257/103; 438/46; 257/E33.025

(57) ABSTRACT

The present invention provides a light emitting diode comprising a substrate: a nitride semiconductor layer formed on the substrate; an ITO mask pattern formed on the nitride semiconductor layer; an N-type semiconductor layer formed through lateral growth on the nitride semiconductor layer and the ITO mask pattern; and a P-type semiconductor layer formed on the N-type semiconductor layer. In a nitride semiconductor light emitting diode of the present invention, a nitride semiconductor layer is formed through lateral growth, so that crystal defects can be reduced, thereby enhancing the crystallinity of the semiconductor layer. Accordingly, the performance of the light emitting diode can be enhanced, and the reliability thereof can be secured. Particularly, there is an advantage in that since ITO with high electrical conductivity is used as a mask pattern for lateral growth, so that a current spreading property is improved, thereby enhancing light emitting efficiency.

### CROSS REFERENCE RELATED APPLICATIONS

This application is the National Stage of International Application No. PCT/KR2007/000487, filed on Jan. 29, 2007, and claims priority from and the benefit of Korean Patent Application No. 10-2006-0010284, filed on Feb. 2, 2006, which are both hereby incorporated by reference for all purposes as if fully set forth herein.

### FIELD OF THE INVENTION

The present invention relates to a light emitting diode and a method of fabricating the same, and more particularly, to a nitride semiconductor light emitting diode, wherein crystal defects can be reduced by using lateral growth and light emitting efficiency can be enhanced by improving a current spreading property, and a method of fabricating the nitride semiconductor light emitting diode.

### DISCUSSION OF THE BACKGROUND

Light emitting diodes have less electric power consumption and a longer life span, can be installed in a narrow space and have strong resistance against vibration as compared with conventional light bulbs or fluorescent lamps. Since such light emitting diodes have reduced electric power consumption and excellent durability, the light emitting diodes have been used as display devices and backlights. Recently, studies on application of the light emitting diodes to general illumination have been actively conducted.

Among compound semiconductor materials, a nitride based semiconductor material has an excellent light emitting characteristic in visible and UV light ranges. The nitride based semiconductor material is also used in high-output and high-frequency electronic devices. Particularly, GaN has a direct transition bandgap of 3.4 eV at normal temperature. As the GaN may be combined with a material such as InN or AlN to have a direct transition bandgap of 1.9 eV (InN) to 3.4 eV (GaN) or 6.2 eV (AlN), the GaN can emit light in a broad wavelength range of visible light to UV light. For this reason, the GaN is a material with high applicability to optical devices.

A nitride semiconductor is generally grown on a heterogeneous substrate such as sapphire or silicon carbide. “heterogeneous substrate” as used herein means a substrate made of a material different from upper semiconductor layers grown on which. However, since differences in lattice constants and thermal expansion coefficients between the nitride semiconductor and the heterogeneous substrate are large, it is very difficult to grow a nitride semiconductor thin film with good quality.

FIG. 1 is a sectional view schematically showing a conventional nitride semiconductor light emitting diode.

Referring to FIG. 1, the light emitting diode comprises a substrate 1; a buffer layer 2 formed on the substrate 1; and an N-type semiconductor layer 3, an active layer 4 and a P-type semiconductor layer 5, which are sequentially formed on the buffer layer 2.

The P-type and N-type semiconductor layers 5 and 3 respectively formed on top and bottom surfaces of the active layer 4 supply a current to the active layer 4 so that the active layer 4 can emit light. In a general GaN semiconductor light emitting diode, a GaN semiconductor compound doped with Mg is used as the P-type semiconductor layer 5, and a GaN semiconductor compound doped with Si is used as the N-type semiconductor layer 3.

In such a light emitting diode, great mismatch in lattice constants and thermal coefficients can be reduced by means of a method of forming an AlN or low temperature GaN buffer layer and subsequently growing a nitride semiconductor thin film. Nevertheless, the buffer layer has crystal defects due to the great mismatch in lattice constants and thermal coefficients between the buffer layer and the substrate. Since the crystal defect is transmitted to the nitride semiconductor thin film as it is, the nitride semiconductor thin film has a threading dislocation of about 10⁹/cm². Therefore, it is still difficult to form a nitride semiconductor thin film with high quality.

As another method of reducing crystal defects, there is a method of growing a nitride semiconductor thin film through lateral growth.

In a lateral epitaxial overgrowth (LEO) process, a nitride semiconductor thin film is selectively subjected to vertical or horizontal growth on a heterogeneous substrate, such as sapphire, silicon or silicon carbide, depending on a mask or a pattern of the substrate, and a threading dislocation is blocked in a horizontal growth region, so that the threading dislocation can be prevented from penetrating into a surface. For example, in a case where a mask pattern is formed, a nitride semiconductor thin film is subjected to lateral growth depending on the mask pattern, and the transmission of a defect is prevented at a portion where the mask pattern is formed. All techniques of Pendeo-Epitaxy (PE), Cantilever Epitaxy (CE), Lateral Epitaxy on Patterned Sapphire (LEPS) and the like are techniques for preventing a threading dislocation from penetrating into a surface by means of horizontal growth, which are modified versions of the LEO process.

In case of a conventional light emitting diode, a mask pattern is formed using an insulation material such as SiO₂ or SiN in such a lateral epitaxial overgrowth process. However, the mask pattern of such an insulation material have no influence on the flow of a current in an N-type semiconductor layer. On the contrary, there is a risk that the flow of a current may be blocked due to an insulation property of the mask pattern. Accordingly, there is a disadvantage in that the conventional light emitting diode has a poor current spreading property, resulting in deterioration of light emitting efficiency.

### SUMMARY OF THE INVENTION

Accordingly, the present invention is conceived to solve the aforementioned problems. An object of the present invention is to provide a nitride semiconductor light emitting diode, wherein crystal defects in a nitride semiconductor layer can be reduced by using a lateral growth process and an excellent current threading property can be obtained by forming an ITO pattern, and a method of fabricating the nitride semiconductor light emitting diode.

To achieve the object, the present invention provides a light emitting diode comprising a substrate; a nitride semiconductor layer formed on the substrate; an ITO mask pattern formed on the nitride semiconductor layer; an N-type semiconductor layer formed through lateral growth on the nitride semiconductor layer and the ITO mask pattern; and a P-type semiconductor layer formed on the N-type semiconductor layer.

The ITO mask pattern may include a stripe or lattice configuration, and the nitride semiconductor layer may include concave and convex portions partially etched according to the ITO mask pattern.

The light emitting diode may further comprise a buffer layer containing GaN, InN or AlN between the substrate and the nitride semiconductor layer.

The present invention provides a method of fabricating a light emitting diode, comprising the steps of: forming a nitride semiconductor layer on a substrate; forming an ITO mask pattern on the nitride semiconductor layer; forming an N-type semiconductor layer through lateral growth on the nitride semiconductor layer and the ITO mask pattern; and forming a P-type semiconductor layer on the N-type semiconductor layer.

The method may further comprise the step of etching predetermined portions of the nitride semiconductor layer using the ITO mask pattern as an etching mask after the step of forming the ITO mask pattern.

The method may further comprise the step of forming a buffer layer containing GaN, InN or AlN between the substrate and the nitride semiconductor layer.

According to the present invention, a nitride semiconductor layer is formed through lateral growth in a nitride semiconductor light emitting diode, so that crystal defects can be reduced, thereby enhancing the crystallinity of the semiconductor layer. Accordingly, the performance of the light emitting diode can be improved, and reliability thereof can be secured.

Particularly, there is an advantage in that ITO with high electrical conductivity is used for a mask pattern for lateral growth, so that a current threading property is improved, thereby enhancing light emitting efficiency.

### BRIEF DESCRIPTION OF THE DRAWINGS

FIG. 1 is a sectional view schematically showing a conventional nitride semiconductor light emitting diode.

FIG. 2 is a sectional view schematically illustrating a nitride semiconductor light emitting diode according to the present invention.

FIGS. 3 and 4 are sectional views showing examples of an ITO mask pattern according to the present invention.

FIGS. 5 to 8 are sectional views illustrating a method of fabricating a light emitting diode according to the present invention.

FIG. 9 is a sectional view showing a light emitting diode according to an embodiment of the present invention.

FIG. 10 is a sectional view showing a light emitting diode according to another embodiment of the present invention.

FIG. 11 is a sectional view showing a light emitting diode according to a further embodiment of the present invention.

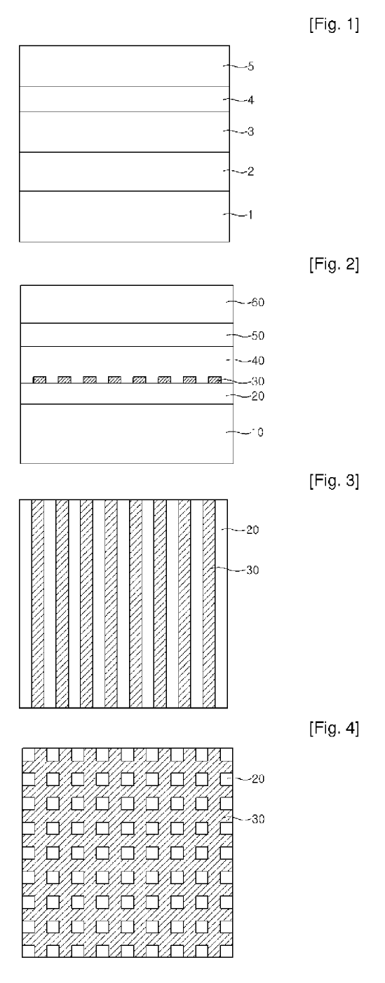

### DETAILED DESCRIPTION OF THE ILLUSTRATED EMBODIMENTS

Hereinafter, preferred embodiments of the present invention will be described in detail with reference to the accompanying drawings. However, the present invention is not limited to the embodiments but may be implemented into different forms. These embodiments are provided only for illustrative purposes and for full understanding of the scope of the present invention by those skilled in the art. Throughout the drawings, like elements are designated by like reference numerals.

FIG. 2 is a sectional view schematically illustrating a nitride semiconductor light emitting diode according to the present invention.

Referring to FIG. 2, the light emitting diode comprises a substrate 10; a nitride semiconductor layer 20 formed on the substrate 10; a mask pattern 30 formed on the nitride semiconductor layer 20; an N-type semiconductor layer 40 formed through lateral growth on the nitride semiconductor layer 20 and the mask pattern 30; an active layer 50 formed on the N-type semiconductor layer 40; and a P-type semiconductor layer 60. ITO (Indium Tin Oxide) with high electrical conductivity is used for the mask pattern 30.

A nitride semiconductor is generally grown on a heterogeneous substrate such as sapphire or silicon carbide. However, since differences in lattice constants and thermal expansion coefficients between the nitride semiconductor and the heterogeneous substrate are great, it is very difficult to grow a nitride semiconductor thin film with good quality. Thus, the present invention intends to reduce crystal defects by forming a nitride semiconductor thin film through lateral growth. Particularly, an excellent current spreading property can be obtained by using ITO with high electrical conductivity for a mask pattern for the lateral growth.

Sapphire (Al2O3), silicon carbide (SiC), silicon (Si) or the like is used for the substrate 10.

The nitride semiconductor layer 20 is an undoped nitride semiconductor layer. The nitride semiconductor layer 20 may further include concave and convex portions partially etched according to the mask pattern 30.

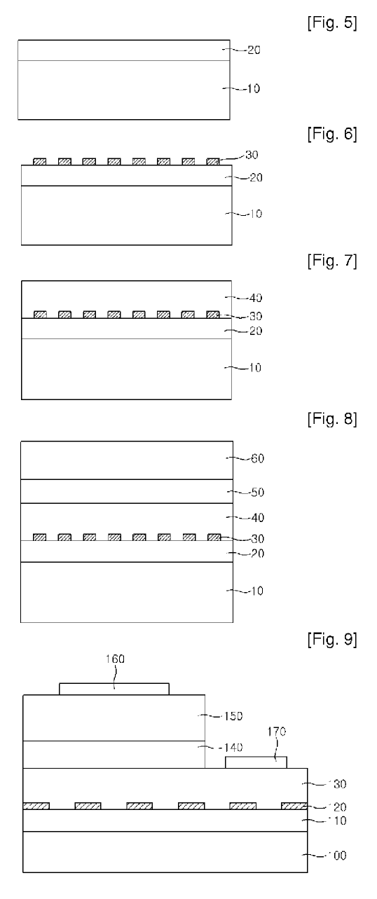

As described above, ITO is used for the mask pattern 30 formed on the nitride semiconductor layer 20. The mask pattern may be formed into a stripe configuration as shown in FIG. 3 or into a lattice configuration as shown in FIG. 4. However, the configuration of the mask pattern 30 is not limited thereto but may vary differently.

The N-type semiconductor layer 40 formed through lateral growth on the nitride semiconductor layer 20 and the mask pattern 30 is a layer in which electrons are produced. Preferably, GaN doped with N-type impurities is used for the N-type semiconductor layer. The N-type semiconductor layer is not limited thereto but may be a layer formed of various materials with semiconductor properties.

The active layer 50 is a region that has a predetermined bandgap and is formed with quantum wells so that electrons and holes are recombined. The active layer may contain InGaN. The wavelength of emitted light, which is generated due to the combination of electrons and holes, varies depending on the kind of material constructing the active layer 50. Therefore, it is preferred that a semiconductor material contained in the active layer 50 be controlled depending on a desired wavelength.

Further, the P-type semiconductor layer 60 is a layer in which holes are produced. Preferably, GaN doped with P-type impurities is used for the P-type semiconductor layer. The P-type semiconductor layer is not limited thereto but may be a layer formed of various materials with semiconductor properties.

The light emitting diode of the present invention is not limited to the foregoing. That is, the material layer may be omitted or modified, or various material layers may be added, depending on properties of a device and convenience of a process. For example, a buffer layer (not shown) for reducing lattice mismatch between the substrate 10 and the subsequent layers may be further formed between the substrate 10 and the nitride semiconductor layer 20. The buffer layer may contain GaN, InN or AlN, which is a semiconductor material. Further, in order to increase light emitting efficiency, a P-type cladding layer of AlGaN or the like, which has a larger energy bandgap, may be additionally formed between the active layer 50 and the P-type semiconductor layer 60.

In addition, as shown in the figures, the N-type semiconductor layer 40 formed through lateral growth is placed on the nitride semiconductor layer 20 with the mask pattern 30 formed thereon. However, in order to more enhance the crystallinity of a semiconductor thin film, an additional nitride semiconductor layer may further included between the nitride semiconductor layer 20 with the mask pattern 30 formed thereon and the N-type semiconductor layer 40.

As described above, in the light emitting diode of the present invention, a nitride semiconductor layer is formed through lateral growth, so that crystal defects can be reduced, thereby enhancing the crystallinity of a semiconductor thin film. Accordingly, the performance of the light emitting diode can be enhanced and reliability thereof can be secured. Further, there is an advantage in that ITO with high electrical conductivity is used for a mask pattern for lateral growth, so that a current threading property is improved, thereby enhancing light emitting efficiency.

FIGS. 5 to 8 are sectional views illustrating a method of fabricating a light emitting diode according to the present invention.

Referring to FIG. 5, a nitride semiconductor layer 20 is formed on a substrate 10.

The substrate 10 refers to a typical wafer for use in fabricating a light emitting diode, and the substrate 10 is made of any one of Al2O3, SiC, ZnO, Si, GaAs, GaP, LiAl2O3, BN, AlN and GaN. The crystal growth substrate 10 made of sapphire (Al2O3) is used in this embodiment.

When subsequent layers are subjected to crystal growth on the substrate 10, a buffer layer (not shown) for reducing lattice mismatch between the substrate 10 and the subsequent layers may be formed. The buffer layer may contain GaN, InN or AlN, which is a semiconductor material.

The nitride semiconductor layer 20 is an undoped nitride semiconductor layer, and GaN may be used for the nitride semiconductor layer.

Referring to FIG. 6, a mask pattern 30 made of ITO is formed on the nitride semiconductor layer 20. To this end, an ITO layer is formed on the nitride semiconductor layer 20 through a certain deposition process. A photoresist is applied on the ITO layer, and a photoresist pattern is then formed through a photolithographic process using a predetermined mask. The ITO layer is partially removed by performing an etching process using the photoresist pattern as an etching mask, so that the mask pattern 30 can be formed.

The mask pattern 30 may be formed into a stripe configuration as shown in FIG. 3. Further, in order to more improve a current threading effect, the mask pattern may be formed into a lattice configuration in which all of a plurality of stripes are connected to one another as shown in FIG. 4. It will be apparent that the aforementioned mask pattern is not limited thereto but may vary differently.

Referring to FIG. 7, an N-type semiconductor layer 40 is formed on the nitride semiconductor layer 20 with the mask pattern 30 formed thereon. To this end, the N-type semiconductor layer 40 is formed by implanting N-type impurities into a semiconductor layer formed through lateral growth on the nitride semiconductor layer 20 and the mask pattern 30.

The N-type semiconductor layer 40 is a layer in which electrons are produced, and may be formed as an N-type compound semiconductor layer and an N-type clad layer. At this time, it is preferred that GaN doped with N-type impurities be used for the N-type compound semiconductor layer. The N-type compound semiconductor layer is not limited thereto but may be a layer formed of various materials with semiconductor properties.

A semiconductor thin film is formed on portions of the surface of the nitride semiconductor layer 20, which are exposed because the mask pattern 30 is not formed, and lateral growth is performed on the mask pattern 30, so that the N-type semiconductor layer 40 with a substantially flat surface can be formed. At this time, in a region where the mask pattern 30 is formed, crystal defects are prevented from being transmitted from the nitride semiconductor layer 20, and thus, the crystal defects do not exist therein due to lateral growth.

The N-type semiconductor layer 40 formed through such lateral growth has reduced crystal defects and thus is formed as a semiconductor thin film with high quality.

Alternatively, the N-type semiconductor layer 40 may be formed by forming the ITO mask pattern 30 and etching predetermined portions of the nitride semiconductor layer 20 using the mask pattern 30 as an etching mask. In this case, lateral growth is made upwardly from a side surface of the etched nitride semiconductor layer 20 upon formation of the N-type semiconductor layer 40. The lateral growth is also made on the mask pattern 30. Accordingly, there is an advantage in that crystal defects can be reduced due to the lateral growth.

Referring to FIG. 8, an active layer 50 and a P-type semiconductor layer 60 are sequentially formed on the N-type semiconductor layer 40.

The active layer 50 is a region that has a predetermined bandgap and is formed with quantum wells so that electrons and holes are recombined. The active layer may contain InGaN. Further, the wavelength of emitted light, which is generated due to the combination of electrons and holes, varies depending on the kind of material constructing the active layer 50. Therefore, it is preferred that a semiconductor material contained in the active layer 50 be controlled depending on a desired wavelength.

Further, the P-type semiconductor layer 60 is a layer in which holes are produced. At this time, it is preferred that AlGaN doped with P-type impurities be used for the P-type semiconductor layer. The P-type semiconductor layer is not limited thereto but may be a layer formed of various materials with semiconductor properties.

The aforementioned material layers are formed through various deposition and growth methods including metal organic chemical vapor deposition (MOCVD), chemical vapor deposition (CVD), plasma-enhanced chemical vapor deposition (PCVD), molecular beam epitaxy (MBE), hydride vapor phase epitaxy (HVPE) and the like.

Accordingly, it is possible to fabricate a light emitting diode including a high-quality nitride semiconductor layer subjected to lateral growth using an ITO mask pattern.

The aforementioned method of fabricating the light emitting diode of the present invention is not limited thereto, and various processes and fabrication methods may be modified or added depending on properties of devices and convenience of a process. For example, an additional nitride semiconductor layer is formed through lateral growth on the nitride semiconductor layer with the mask pattern formed thereon, and an N-type semiconductor layer may be then formed.

FIG. 9 is a sectional view showing a light emitting diode according to an embodiment of the present invention.

Referring to this figure, the light emitting diode comprises a substrate 100; a nitride semiconductor layer 110 formed on the substrate 100; a mask pattern 120 made of ITO and formed on the nitride semiconductor layer 110; an N-type semiconductor layer 130 formed on the nitride semiconductor layer 110 and the mask pattern 120; an active layer 140 formed on a portion of the N-type semiconductor layer 130; and a P-type semiconductor layer 150. The light emitting diode comprises P-type and N-type electrodes 160 and 170 respectively formed on the P-type semiconductor layer 150 and an exposed portion of the N-type semiconductor layer 130. The nitride semiconductor layer 110 contains GaN.

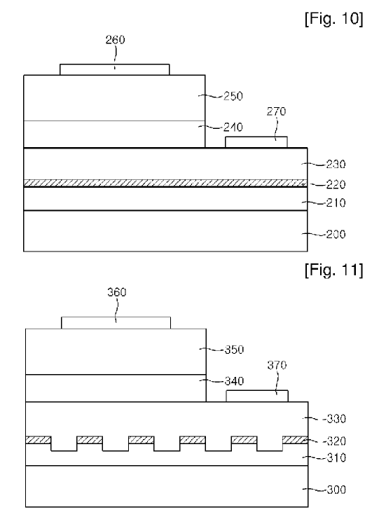

Although the mask pattern 120 in this embodiment is formed into a lattice configuration, a mask pattern 220 made of the ITO may be formed into a stripe configuration in which a plurality of lines extend in a direction from an N-type electrode to a P-type electrode as shown in FIG. 10, so that a current spreading effect can be expected.

The fabricating process of this embodiment will be briefly described below.

A GaN semiconductor layer 110 and an ITO mask pattern 120 are formed on a substrate 100 through the aforementioned method, and an N-type semiconductor layer 130 is formed through lateral growth. Accordingly, it is possible to obtain the N-type semiconductor 130 with reduced crystal defects. In this embodiment, a GaN layer doped with Si atoms is formed as the N-type semiconductor layer 130.

An active layer 140 is formed on the N-type semiconductor layer 130 by controlling a semiconductor material depending on a desired wavelength. In this embodiment, InGaN/GaN capable of emitting green to UV light with wavelengths of 390 to 550 nm is grown.

A P-type semiconductor layer 150 doped with P-type impurities is formed on the active layer 140. In this embodiment, a GaN layer doped with Mg atoms is formed as the P-type semiconductor layer 150.

Next, the P-type semiconductor layer 150 and the active layer 140 are partially removed through a certain etching process so that a portion of the N-type semiconductor layer 130 is exposed, and P-type and N-type electrodes 160 and 170 are then formed on the P-type semiconductor layer 150 and the exposed portion of the N-type semiconductor layer 130, respectively.

To this end, an etching mask pattern is formed on the P-type semiconductor layer 150, and the P-type semiconductor layer 150 and the active layer 140 are removed by performing a dry or wet etching process such that the N-type semiconductor layer 130 is partially exposed. Thereafter, the etching mask pattern is removed, and the P-type and N-type electrodes 160 and 170 are formed on the P-type semiconductor layer 150 and the exposed portion of the N-type semiconductor layer 130, respectively.

A transparent electrode layer for reducing the resistance of the P-type semiconductor layer 150 and enhancing the transmittance of light may be further formed between the P-type semiconductor layer 150 and the P-type electrode 160. ITO (Indium Tin Oxide), ZnO or a transparent metal with electrical conductivity may be used for the transparent electrode layer. Further, an additional ohmic metal layer for smooth supply of a current may be further formed on the P-type semiconductor layer 150 or the exposed portion of the N-type semiconductor layer 130 before forming the P-type and N-type electrodes 160 and 170. Cr or Au may be used for the ohmic metal layer.

FIG. 11 is a sectional view showing a light emitting diode according to a further embodiment of the present invention.

Referring to this figure, the light emitting diode comprises a substrate 300; a nitride semiconductor layer 310 having concave and convex portions on the substrate 300; a mask pattern 320 made of ITO formed on protruding upper surfaces of the concave and convex portions; and an N-type semiconductor layer 330 formed on the nitride semiconductor layer 310 and the mask pattern 320. Alternatively, the light emitting diode comprises an active layer 340 and a P-type semiconductor layer 350 which are formed on a portion of the N-type semiconductor layer 330, and P-type and N-type electrodes 360 and 370 respectively formed on the P-type semiconductor layer 350 and the exposed portion of the N-type semiconductor layer 330. The nitride semiconductor layer 310 contains GaN.

This embodiment is almost identical with the first embodiment. Descriptions of this embodiment overlapping with those of the previous embodiment will be omitted. In this embodiment, the nitride semiconductor layer 310 formed on the substrate 300 has concave and convex portions so that lateral growth is also made from side surfaces of the concave and convex portions of the nitride semiconductor layer. That is, upon formation of the N-type semiconductor layer 330, lateral growth is made upwardly from the side surfaces of the etched nitride semiconductor layer. Lateral growth is also made on the mask pattern 320. Accordingly, there is an advantage in that crystal defects can be reduced due to the lateral growth.

To this end, as described above, a GaN semiconductor 310 and an ITO mask pattern 320 are formed on a substrate 300, and predetermined portions of the GaN semiconductor layer 310 are etched using the mask pattern 320 as an etching mask. Then, an N-type semiconductor layer 330 is formed through lateral growth so that the N-type semiconductor layer 330 with reduced crystal defects can be obtained.

Thereafter, an active layer 340 and a P-type semiconductor layer 350 are sequentially formed on the N-type semiconductor layer 330.

Next, the P-type semiconductor layer 350 and the active layer 340 are partially removed through a predetermined etching process such that a portion of the N-type semiconductor layer 330 is exposed, and P-type and N-type electrodes 360 and 370 are then formed on the P-type semiconductor layer 350 and the exposed portion of the N-type semiconductor layer 330, respectively.

In the present invention described above, a nitride semiconductor layer is formed through lateral growth, so that crystal defects can be reduced, thereby enhancing the crystallinity of the semiconductor layer. Accordingly, the performance of the light emitting diode can be enhanced, and the reliability thereof can be secured. Further, there is an advantage in that since ITO with high electrical conductivity is used as a mask pattern for lateral growth, a current threading property is improved, thereby enhancing light emitting efficiency.

Although the present invention has been described in connection with the preferred embodiments, the scope of the present invention is not limited thereto but should be construed on the basis of the appended claims. Accordingly, it will be understood by those skilled in the art that various modifications and changes can be made thereto without departing from the scope of the present invention.

1. A light emitting diode, comprising:
a substrate;
a nitride semiconductor layer formed on the substrate;
an ITO mask pattern formed on the nitride semiconductor layer;
an N-type semiconductor layer formed through lateral growth on the nitride semiconductor layer and the ITO mask pattern; and
a P-type semiconductor layer formed on the N-type semiconductor layer.

2. The light emitting diode as claimed in claim 1, wherein the ITO mask pattern includes a stripe or lattice configuration.

3. The light emitting diode as claimed in claim 1, wherein the nitride semiconductor layer includes concave and convex portions partially etched according to the ITO mask pattern.

4. The light emitting diode as claimed in claim 1, further comprising a buffer layer containing GaN, InN or AlN between the substrate and the nitride semiconductor layer.

5. A method of fabricating a light emitting diode, comprising the steps of:
forming a nitride semiconductor layer on a substrate;
forming an ITO mask pattern on the nitride semiconductor layer;
forming an N-type semiconductor layer through lateral growth on the nitride semiconductor layer and the ITO mask pattern; and
forming a P-type semiconductor layer on the N-type semiconductor layer.

6. The method as claimed in claim 5, further comprising the step of:
etching predetermined portions of the nitride semiconductor layer using the ITO mask pattern as an etching mask after the step of forming the ITO mask pattern.

7. The method as claimed in claim 5, further comprising the step of:
forming a buffer layer containing GaN, InN or AlN between the substrate and the nitride semiconductor layer.

8. The light emitting diode as claimed in claim 2, wherein the nitride semiconductor layer includes concave and convex portions partially etched according to the ITO mask pattern.

9. The light emitting diode as claimed in claim 2, further comprising a buffer layer containing GaN, InN or AlN between the substrate and the nitride semiconductor layer.

10. The method as claimed in claim 6, further comprising the step of:
forming a buffer layer containing GaN, InN or AlN between the substrate and the nitride semiconductor layer.
